(19) United States
(12) Patent Application Publication
(10) Pub. No.: US 2026/0293492 A1
(43) Pub. Date: Sep. 24, 2026

(54) DISPLAY MODULE AND DISPLAY DEVICE HAVING THE SAME

(71) Applicant: Shanghai Tianma Microelectronics Co., Ltd., Shanghai (CN)

(72) Inventors: Weiqiang ZHU, Shanghai (CN); Yanhua LIU, Shanghai (CN)

(73) Assignee: Shanghai Tianma Microelectronics Co., Ltd., Shanghai (CN)

(21) Appl. No.: 19/221,445

(22) Filed: May 28, 2025

(30) Foreign Application Priority Data
Feb. 20, 2025 (CN) 202510194545.9

(51) Int. Cl. H10K 59/80; H10K 102/00

(52) U.S. Cl. CPC H10K 59/872; H10K 2102/311; H10K 2102/351

(57) ABSTRACT

The present application discloses a display module and a display device having the same. The display module includes a display panel and a support structure that are stacked, the display panel comprising: non-bendable regions and a bendable region connected between two said non-bendable regions, the bendable region being bent toward a side facing away from the support structure when the display module is in a bent state; and the support structure comprising: first support portions corresponding to the non-bendable regions and having a first hardness; and a second support portion disposed corresponding to at least the bendable region, the second support portion having a second hardness less than the first hardness.

### CROSS-REFERENCE TO RELATED APPLICATION

This application claims priority to Chinese Patent Application No. 202510194545.9, filed on Feb. 20, 2025, which is hereby incorporated by reference in its entirety.

### TECHNICAL FIELD

The present application relates to the technical field of display, and in particular to a display module and a display device having the same.

### BACKGROUND

The screen bending region of foldable screen equipment is prone to damage, which is caused by local stress concentration resulting from bending the screen bending region. In order to solve the damage when the screen is bent, the prior art adopts a steel sheet as a support structure. However, the steel sheet has high weight and expensive price, which does not conform to the current development trend of thinning and portability of intelligent devices. The support layer combining flexibility and rigidity has gradually developed in the field of foldable screens.

However, in the support layer combining flexibility and rigidity currently used, the two materials have different hardness and characteristics and are prone to gaps. The above gaps easily lead to unstable connection of the support layers, poor support stability in the bending region, and unstable fit of the support structure, which ultimately leads to easy bending and deformation of the display module.

### SUMMARY

The present application provides a display module and a display device having the same, so as to solve the problems of poor stability and easy bending and deformation caused by using a rigid material to support a display panel in a display module in the prior art.

According to an aspect of the present application, there is provided a display module which includes a display panel and a support structure that are stacked, the display panel comprising: non-bendable regions and a bendable region connected between two non-bendable regions, the bendable region being bent toward a side facing away from the support structure when the display module is in a bent state; and the support structure comprising: a first support portion corresponding to the non-bendable regions and having a first hardness; and a second support portion disposed at least corresponding to the bendable region, the second support portion having a second hardness less than the first hardness.

According to another aspect of the present application, a display device comprising the display module as described above is provided.

### BRIEF DESCRIPTION OF THE DRAWINGS

The accompanying drawings, which form a part of the present application, are intended to provide a further understanding of the present application, and the schematic embodiments of the present application and the description thereof are intended to explain the present application, and do not constitute an undue limitation of the present application. In the drawings:

FIG. 1 is a partial cross-sectional structural schematic diagram of a display module according to an embodiment of the present application;

FIG. 2 is a schematic cross-sectional structural schematic diagram of the display module shown in FIG. 1 in a bent state;

FIG. 3 is a partial cross-sectional structural schematic diagram of another display module according to an embodiment of the present application;

FIG. 4 is a schematic cross-sectional structural diagram of the display module shown in FIG. 3 in a bent state;

FIG. 5 is a partial cross-sectional structural schematic diagram of yet another display module according to an embodiment of the present application;

FIG. 6 is a cross-sectional structural schematic diagram of the display module shown in FIG. 5 in a bent state;

FIG. 7 is a partial cross-sectional structural schematic diagram of still yet another display module according to an embodiment of the present application;

FIG. 8 is a cross-sectional structural schematic diagram of the display module shown in FIG. 7 in a bent state;

FIG. 9 is a partial cross-sectional structural diagram of a display module in a bent state;

FIG. 10 is a schematic structural diagram of a region A in the display module shown in FIG. 9;

FIG. 11 is a partial cross-sectional structural schematic diagram of a first support protrusion and a second support protrusion in a display module according to an embodiment of the present application;

FIG. 12 is a partial cross-sectional structural schematic diagram of a second support part in a display module according to an embodiment of the present application;

FIG. 13 is a partial cross-sectional structural schematic diagram of a first support portion in a display module according to an embodiment of the present application;

FIG. 14 is a schematic structural diagram of a display device according to an embodiment of the present application; and

FIG. 15 is a schematic structural diagram of the display device shown in FIG. 14 in a bent state.

### REFERENCE NUMERALS

1. Display device; 2. Non-display area; 3. Display area; 10. Display panel; 110. Bendable region; 111. First bendable region; 112. Second bendable region; 120. Non-bendable region; 20. Support structure; 210. First support portion; 220. Second support portion; 221. First support region; 222. Second support region; 223. Connection region; 230. Support protrusion; 2301. First sub-protrusion; 2302. Second sub-protrusion; 231. First support protrusion; 2310. Accommodation protrusion; 232. Second support protrusion; 2320. Accommodation groove; 240. Base body; 250. Embedded structure; 260. Accommodation cavity.

### DETAILED DESCRIPTION

It should be noted that the embodiments and features in the embodiments in the present application may be combined with each other as long as there is no conflict. Hereinafter, the present application will be described in detail with reference to the accompanying drawings in conjunction with embodiments.

In order to make those skilled in the art better understand the solutions of the present application, the technical solutions in the embodiments of the present application will be clearly and completely described below with reference to the accompanying drawings in the embodiments of the present application. It is obvious that the described embodiments are only part of the embodiments of the present application, but not all of the embodiments. Based on the embodiments in the present application, all other embodiments obtained by those skilled in the art without creative work should belong to the scope of protection of the present application.

It should be noted that the terms “first”, “second”, and the like in the specification, claims, and drawings of the present application are used to distinguish similar objects, and are not necessarily used to describe a specific order or sequence. It should be understood that the data so used may be interchangeable where appropriate so that the embodiments of the present application described herein. Furthermore, the terms “comprising” and “having” and any variations thereof are intended to cover a non-exclusive inclusion. For example, a process, method, system, product, or apparatus comprising a series of steps or units is not necessarily limited to those steps or units clearly listed but may include other steps or units not clearly listed or inherent to such processes, methods, products, or apparatuses.

As mentioned in the background, in the support layer combining flexibility and rigidity currently used, the two materials have different hardness and different characteristics, which can easily lead to gaps. These gaps can cause unstable connections in the support layer, poor support stability in the bending region, and unstable coordination of the support structure, ultimately resulting in the display module being prone to bending and deformation. To solve the above technical problems, the embodiments of the present application provide a display module and a display device having the same.

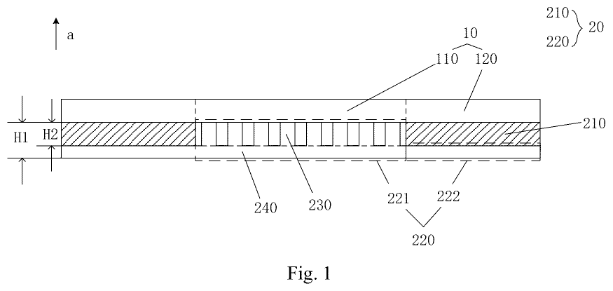

According to an embodiment of the present application, as shown in FIGS. 1 to 4, there is provided a display module which includes a display panel 10 and a support structure 20 that are stacked. The display panel 10 includes a bendable region 110 and non-bendable regions 120, the bendable region 110 being connected between two non-bendable regions 120, and the bendable region 110 being bent toward a side away from the support structure 20 when the display module is in a bent state. The support structure 20 includes first support portions 210 which are arranged corresponding to the non-bendable regions 120 and have a first hardness; and the support structure 20 also includes a second support portion 220 which is arranged corresponding to at least the bendable region 110 and has a second hardness less than the first hardness.

According to the display module in the above embodiment, since the first hardness of the first support portion 210 corresponding to the non-bendable region 120 is greater than the second hardness of the second support portion 220 at least corresponding to the bendable region 110, the support structure 20 can be designed to correspond to the bending characteristics of the non-bendable region 120 of the display panel 10 that needs a hard support and the bending characteristics of the bendable region that needs a soft support by adopting materials with greater hardness in the non-bendable region 120 and materials with less hardness in the bendable region, respectively. This design provides effective support for the non-bendable region 120 and the bendable region 110 of the display panel 10 when the display module is unfolded and folded, avoiding excessive stress on the bendable region 110 of the display panel 10 and prolonging the service life of the display module. Therefore, in the present application, the first support portion 210 and the second support portion 220 are closely connected in a manner of an embedding-fitting, thereby improving the supporting stability of the support structure 20 for the display panel 10, avoiding the bending deformation of the support layer after the display module is bent multiple times, and solving the problem of poor stability and easy bending deformation caused by the use of rigid materials to support the display panel 10 in the prior art display module.

The above is the core idea of the present application, and the technical solutions in the embodiments of the present application will be clearly and completely described below with reference to the accompanying drawings in the embodiments of the present application. Based on the embodiments in the present application, all other embodiments obtained by those skilled in the art without making creative efforts belong to the scope of protection of the present application.

In the display module of an embodiment of the present application, as shown in FIG. 1, the display panel 10 includes a bendable region 110 and non-bendable regions 120. The second support portion 220 may include a first support region 221 and second support regions 222. The first support region 221 is connected between two of second support regions 222, the first support portion 210 is located between the second support region 222 and the non-bendable region 120, the first support region 221 corresponds to the bendable region 110, and the second support region 222 corresponds to the non-bendable region 120.

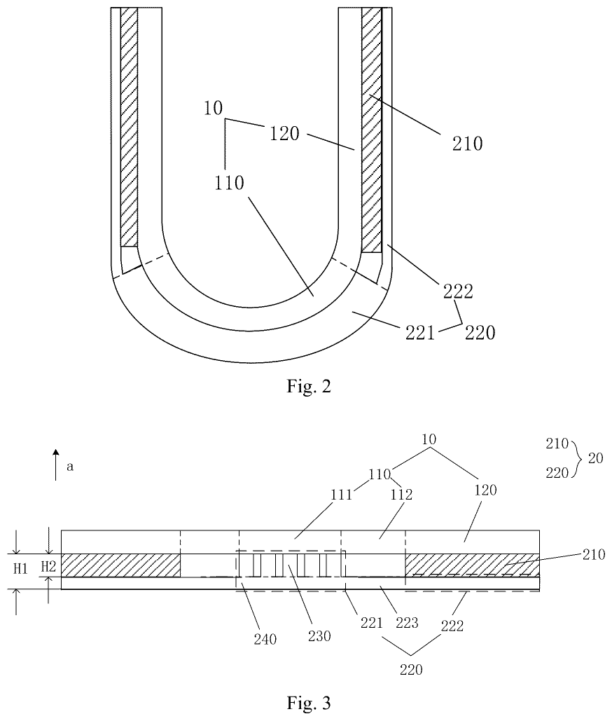

Specifically, when the display module is used as a foldable screen, the display panel 10 can be divided into a bendable region 110 and non-bendable regions 120, and the bendable region 110 is connected between two non-bendable regions 120. FIG. 2 is a schematic cross-sectional structural schematic diagram of the display module shown in FIG. 1 in a bent state. When the display module is in a bent state, as shown in FIG. 2, the bendable region 110 is bent toward the side away from the support structure 20. The second support portion 220 can also be divided into a first support region 221 and support regions 222, and the first support portion 210 is located between the second support region 222 and the non-bendable region 120. In this case, due to the second hardness of the second support region 222 being lower than the first hardness of the first support portion 210, the hardness of the support structure 20 gradually increases in the direction towards the non-bendable region 120, and the first support portion 210 with higher hardness can enhance the structural rigidity of the non-bendable region 120. At the same time, since the portion of the support structure 20 corresponding to the bendable region 110 is the second support portion 220 having the second hardness, the support structure 20 always maintains a low hardness in the direction towards the bendable region 110, so that the non-bendable region 120 and the bendable region 110 of the display panel 10 can be effectively supported, excessive stress on the display panel 10 in the bending region is avoided, and the service life of the display module is prolonged.

In the display module in another embodiment of the present application, as shown in FIG. 3, the display panel 10 includes a bendable region 110 and non-bendable regions 120, and the bendable region 110 may include a first bendable region 111 and second bendable regions 112. The second support portion 220 may include a first support region 221, second support regions 222, and connection regions 223, and the connection regions 223 are configured to connect the two second support regions 222 and the first support region 221. The first support portion 210 is located between the second support regions 222 and the non-bendable regions 120. The first support region 221 corresponds to the first bendable region 111, the connection regions 223 correspond to the second bendable regions 112 respectively, and the second support regions 222 correspond to the non-bendable regions 120 respectively.

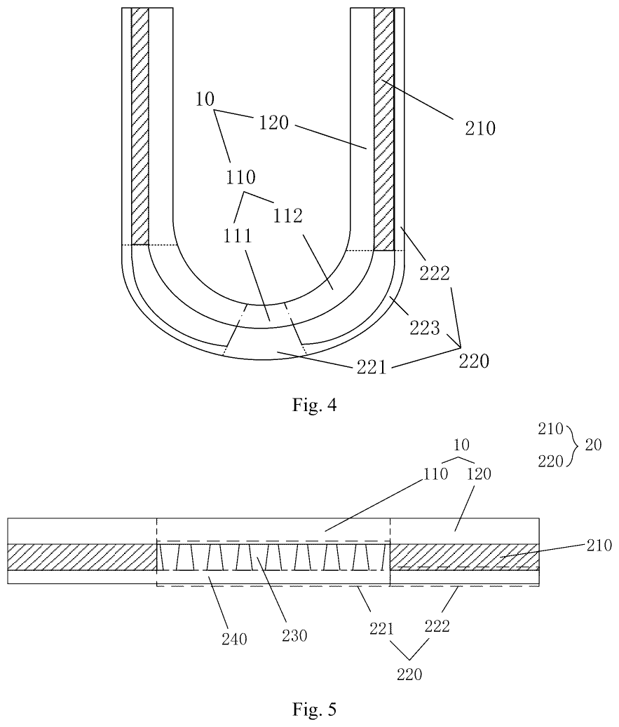

Specifically, when the display module is used as a foldable screen, the display panel 10 can be divided into a first bendable region 111, second bendable regions 112, and non-bendable regions 120, and the second bendable regions 112 are connected between the two non-bendable regions 120 and the first bendable region 111 respectively. FIG. 4 is a schematic cross-sectional structural diagram of the display module shown in FIG. 3 in a bent state. When the display module is in a bent state, as shown in FIG. 4, the bendable region 110 with the first bendable region 111 and the second bendable regions 112 is bent towards the side away from the support structure 20. The second support portion 220 can also be divided into a first support region 221, second support regions 222, and connection regions 223. The first support portion 210 is located between the second support regions 222 and the non-bendable regions 120. At this time, due to the second hardness of the second support regions 222 being lower than the first hardness of the first support portion 210, the hardness of the support structure 20 gradually increases in the direction close to the non-bendable regions 120. The first support portion 210 with higher hardness can enhance the structural rigidity of the non-bendable regions 120. At the same time, since the portion of the support structure 20 corresponding to the bendable region 110 is the second support portion 220 having the second hardness, the support structure 20 always maintains a low hardness in the direction close to the bendable region 110. This ensures that both the non-bendable regions 120 and the bendable regions 110 of the display panel 10 can be effectively supported, excessive stress on the display panel 10 in the bendable region is avoided, and the service life of the display module is prolonged.

In some alternative embodiments, as shown in FIGS. 1 and 3, the thickness of the first support region 221 is greater than the thickness of the first support portion 210 in a first direction a, the first direction a is a direction perpendicular to the first surface of the display panel 10, and the first surface is a surface of the display panel 10 opposite to the support structure 20.

In the above-described alternative embodiments, as shown in FIGS. 1 and 3, the thickness of the first support region 221 in the first direction a is H1, and the thickness of the first support portion 210 in the first direction a is H2, where H1 is greater than H2. The thickening of the second support portion 220 in the non-bendable region 120 can provide stronger structural support, ensure the flatness and stability of the non-bendable region 120 when the display module is unfolded, and avoid unnecessary bending or deformation of the non-bendable region 120 due to external force or gravity. Furthermore, the thickness of the second support portion 220 in the non-bendable regions 120 is increased, which helps to improve the stress distribution inside the screen body, especially during the folding and unfolding process, and can reduce the stress concentration between the non-bendable regions 120 and the bendable region, thereby prolonging the service life of the foldable screen.

In the above-described alternative embodiments, as shown in FIGS. 1 and 3, the thickness of the first support region 221 may be the sum of the thicknesses of the second support region 222 and the first support portion 210. By satisfying the thickness relationship between the first support region 221, the second support region 222, and the first support portion 210, the thickness distribution of the entire display module can be balanced, avoiding structural imbalance or poor display effect caused by local thickness differences.

In some alternative embodiments, the hardness of the second support 220 portion is less than the hardness of the first support portion 210, the material of the first support portion 210 includes a rigid material, and the material of the second support portion 220 includes a flexible material.

Specifically, the flexible material forming the first support portion 210 may be selected from any one or more of polydimethylsiloxane (PDMS), polyurethane (PU), polyimide (PI), thermoplastic polyurethane (TPU), and elastomeric rubber, but is not limited to the above. A person skilled in the art makes a reasonable selection according to the prior art.

Specifically, the second support portion 220 may be selected from rigid materials such as metal materials, glass fiber reinforced plastics (GFRP), carbon fiber composite materials, ceramic materials, engineering plastics, and reinforcing plates. The metal materials include but are not limited to stainless steel, aluminum, magnesium alloys, and the like, which have high strength, good thermal stability, and thermal conductivity. Glass fiber reinforced plastic is a composite material that combines the high strength of glass fiber with the lightweight characteristics of plastic and is often used in applications that require higher stiffness and lightweight. Carbon fiber composites also have extremely high strength-to-weight ratios. Engineering plastics include but are not limited to polycarbonate (PC), polyetheretherketone (PEEK), nylon, etc., which have good mechanical properties and heat resistance. Reinforcing plates are composite plates that contain metal or carbon fiber components and that can be used to enhance rigidity in specific areas.

In some alternative embodiments, as shown in FIGS. 1 and 3, a plurality of support protrusions 230 close to the bendable region 110 are provided in the first support region 221. The above-mentioned support protrusions 230 can provide support when the display module is flattened, as shown in FIG. 1, and can also be designed to form a semicircular arc with fixed curvature when the display module is bent, so as to stably support the bendable region, as shown in FIG. 4.

In some optional embodiments, as shown in FIGS. 1 and 3, the second support portion 220 includes a base body 240 and a plurality of the support protrusions 230. The support protrusions 230 are distributed on a side of the base body 240 close to the display panel 10 and have the same height.

In the optional embodiments described above, the support protrusions 230 having equal height can ensure that the stress distribution in the bendable region of the display panel 10 is more uniform during folding and unfolding. This can avoid material fatigue or damage caused by stress concentration and prolong the service life of the display module. Furthermore, when the plurality of support protrusions 230 are equal in height, they can form a preset and uniform radius of curvature when the display module is bent, which helps to reduce the depth of the crease, so that the display module still maintains good visual effect and flatness after folding. Besides, the support protrusions 230 of equal height can closely collaborate with each other during the folding process, which facilitates the formation of a continuous support surface, reduces the gaps between the support protrusions 230, thereby improving the structural stability and mechanical strength of the bendable region, and preventing the display module from being irregularly or excessively bent during folding.

In some optional embodiments, as shown in FIGS. 1 and 3, the orthographic projections of the plurality of support protrusions 230 on the display panel 10 have the same area, and the orthographic projections of the plurality of support protrusions 230 on the display panel 10 have the same shape.

In the above optional embodiment, the support protrusions 230 having the same orthographic projection size mean that they occupy the same area on the plane, so that when they are subjected to pressure, the load can be more evenly distributed to avoid material fatigue or damage caused by excessive stress on a certain part, thereby improving the overall stability and durability. Moreover, during folding and unfolding, the support protrusions 230 of the same orthographic projection size can help the display module form a more consistent curved shape, avoid unsmooth folding or uneven creases caused by uneven size of the support protrusions 230, and improve the display quality and user experience of the display module. In addition, the support protrusions 230 with the same size can simplify the design process, making it more convenient and efficient in the structural design and subsequent manufacturing process. The standardized size also means that the same mold can be used for production, reducing the production cost and time.

Specifically, the shape of orthographic projection of the support protrusion 230 on the display panel 10 may be selected from any one or a combination of a rectangle, a trapezoid, a triangle, a diamond, and a parallelogram, which is not specifically limited in the embodiment of the present application.

It should be noted that although the shape of the cross-section of the support protrusion 230 illustrated in FIGS. 1 and 3 is rectangular, which is not limited to a rectangular in the present application and may be other shapes, such as a trapezoid, a combination of a trapezoid and a rectangular, or some shapes which can form a close arrangement.

In some optional embodiments, as shown in FIG. 5, the second support portion 220 is divided into the first support region 221 and the second support regions 222. The second support portion 220 includes a base body 240 and a plurality of support protrusions 230, each of the support protrusions 230 having the same shape has a second surface and a third surface which are opposite each other, the second surface is located on a side of the third surface close to the display panel 10, and the orthographic projection of the third surface on the first surface is located within the orthographic projection of the second surface on the first surface.

Specifically, with the above-described design of the second surface and the third surface of the support protrusions 230, the shape thereof can be or similar to a trapezoid, which can adaptively adjust its support characteristics according to the angle and degree of bending of the display module. When the display module is unfolded to flatten, the upper base of the trapezoid can provide sufficient support. When the display module is bent, the lower base of the trapezoid can provide a wider support area to ensure the stability and support effect of the display module in different states. Furthermore, compared with the rectangular or other shapes, the trapezoid design can provide more stable support during bending, avoid wobble of the support protrusion 230 from side to side during bending, improve the structural stability of the screen, and reduce the deformation and damage of the bendable region 110.

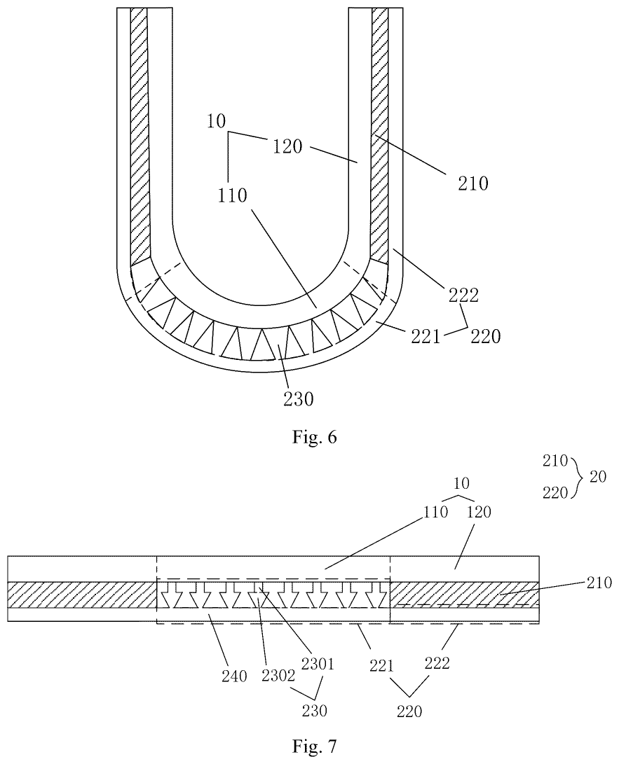

For example, the display module as shown in FIG. 5 is used as a foldable screen. The display panel 10 is divided into a bendable region 110 and non-bendable regions 120, and the bendable region 110 is connected between two non-bendable regions 120. FIG. 6 a cross-sectional structural schematic diagram of the display module shown in FIG. 5 in a bent state. When the display module is in the bent state, as shown in FIG. 6, the bendable region 110 is bent toward the side away from the support structure. The second support portion 220 is divided into the first support region 221 and the second support regions 222. The first support portion 210 is located between the second support region 222 and the non-bendable region 120. The second hardness of the second support region 222 is less than the first hardness of the first support portion 210. The first support portion 210 with greater hardness can enhance the structural rigidity of the non-bendable portions 120. At the same time, the part of the support structure 20 corresponding to the bendable region 110 is the second support portion 220 with the second hardness, so that the support structure 20 always maintains lower hardness in the direction close to the bendable region 110. Therefore, both the non-bendable regions 120 and the bendable region 110 of the display panel 10 can be effectively supported. Furthermore, the trapezoid design of the support protrusions 230 may provide more stable support during bending.

In other optional embodiments, as shown in FIG. 7, the second support portion 220 includes a base body 240 and a plurality of support protrusions 230, each of the support protrusions 230 having the same shape is provided with a first sub-protrusion 2301 and a second sub-protrusion 2302, and the first sub-protrusion 2301 is located on a side of the second sub-protrusion 2302 close to the display panel 10. The first sub-protrusion 2301 has a first orthographic projection on the first surface, the second sub-protrusion 2302 has a second orthographic projection on the first surface, and the size of the first orthographic projection is smaller than the size of the second orthographic projection.

Specifically, the above-described design of the first sub-protrusion 2301 and the second sub-protrusion 2302 can make the support protrusion 230 form a shape similar to a shape of an arrow. The arrow-shaped design can provide multi-point contact when bending, thereby more effectively dispersing stress, reducing stress concentration, and further reducing the formation of creases, and improving the durability of the display module. Furthermore, the arrow-shaped support protrusions 230 can provide good planar support when unfolded, and can naturally form a stable triangular shape when folded. This structure has excellent self-supporting ability, which helps to maintain the shape of the bendable region 110, and reduces deformation and damage when folding.

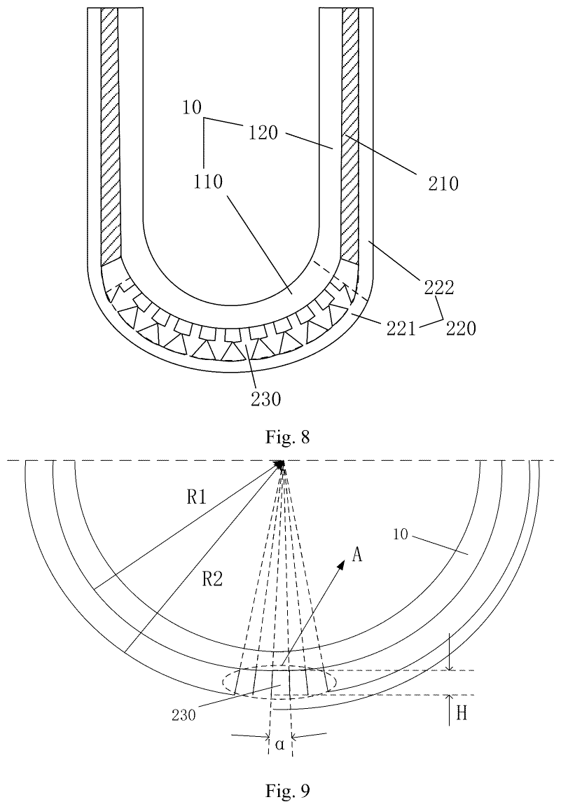

For example, the display module as shown in FIG. 7 is used as a foldable screen. The display panel 10 is divided into a bendable region 110 and non-bendable regions 120, and the bendable region 110 is connected between two non-bendable regions 120. FIG. 8 is a cross-sectional structural schematic diagram of the display module shown in FIG. 7 in a bent state. When the display module is in a bent state, as shown in FIG. 8, the bendable region 110 is bent toward the side away from the support structure. The second support portion 220 is divided into a first support region 221 second support regions 222, and the first support portion 210 is located between the second support region 222 and the non-bendable regions 120. The second hardness of the second support regions 222 is less than the first hardness of the first support portion 210. The first support portion 210 with greater hardness can enhance the structural rigidity of the non-bendable portions 120. At the same time, the part of the support structure 20 corresponding to the bendable region 110 is the second support portion 220 with the second hardness, so that the support structure 20 always maintains lower hardness in the direction close to the bendable region 110. Therefore, both the non-bendable regions 120 and the bendable region 110 of the display panel 10 are effectively supported. Further, the arrow-shaped support protrusion 230 can form a stable triangular shape during the bending process, so that the support protrusion 230 has excellent self-supporting ability for the display panel.

In some optional embodiments, as shown in FIGS. 1, 3, 5, and 7, the plurality of support protrusions 230 are arranged in at least one row on a side of the display panel 10, and the arrangement direction of each row of support protrusions 230 is a direction in which the bendable region 110 points to the non-bendable region 120.

In the above optional embodiments, the support protrusions 230 are arranged in at least one row, which can ensure that each region, especially the bendable region 110, of the display panel 10 is uniformly and stably supported, so as to effectively disperse stress, to avoid damage to and crease of the display panel 10 caused by stress concentration, and to prolong the service life of the display module. Further, the support protrusions 230 may be arranged to be distributed in an array, and the support protrusions 230 distributed in an array form a grid-like support system, which mechanically provides additional stability and strength, reduces the deformation of the support layer during folding and unfolding, and thus improves the structural stability of the whole display module.

In some optional embodiments, as shown in FIGS. 1, 3, 5, and 7, there is the same spacing between any adjacent two of the support protrusions 230. The support protrusions 230 arranged at equal intervals mean that each part on the display panel 10 is supported with the same frequency and the same intensity, which helps to evenly disperse the stress borne by the display panel 10 when folded and unfolded to avoid local stress concentration, thereby reducing the deformation and crease of the display panel 10, and prolonging the service life of the display module. Moreover, in the bendable region 110 of the display panel 10, the support protrusions 230 arranged at equal intervals form a stable array, and the upper ends of the support protrusions 230 are in contact with each other to form a semicircular arc shape that is closely arranged and has a fixed curvature. The closely arranged support protrusions 230 can provide all-around support to the bendable region, so that the interaction between the structures is more orderly. This will not cause the bendable region 110 to deform or wobble from side to side regardless of support imbalance, the rigidity of the structure can be enhanced, the instability of the bendable region 110 is reduced during the folding process, the display module is more stable in the folding state, the creases are reduced, and the service life of the foldable screen is prolonged.

In the optional embodiments described above, the spacing between adjacent support protrusions 230 may satisfy the following preset formula:

$$ΔL = π \times H / n ,$$

where ΔL is the spacing between adjacent support protrusions 230, H is the height of the support protrusions 230, and n is the number of support protrusions 230 located in the same row.

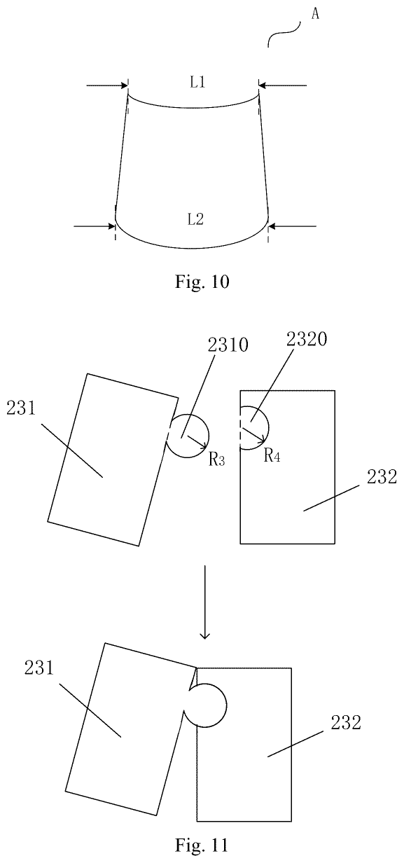

The example where the support protrusions 230 are rectangular in shape is taken for explanation. As shown in FIGS. 9 and 10, FIG. 10 is a schematic diagram of a plurality of support protrusions 230 closely arranged shown in a region A of FIG. 9. The closely arranged support protrusions 230 form a semicircular arc shape with a fixed curvature, and the height of the support protrusions 230 is H. In the case that the display module is in a bent state, the length of the upper inner ring arc in the semicircular arc shape formed by the closely arranged support protrusions 230 is L1, the radius of the circle is R1, the lower outer ring arc length is L2, and the radius of the circle is R2. The arc lengths L1 and L2, the radii R1 and R2, and the number n may satisfy the following relationships:

$$α = π / n , L 1 = α \times R 1 , L 2 = α \times R 2 , R 2 = R 1 + H ;$$

$$L 2 = L 1 = n \times Δ L ,$$

where ΔL is the spacing between adjacent support protrusions 230, and n is the number of the arranged closely support protrusions 230 in the same row that form a semicircular arc shape having a fixed curvature.

When the display panel 10 is bent, the bendable region forms a curvature radius. In order to ensure that the display panel forms a smooth curved surface when bent, it is necessary to make the support protrusions 230 closely arrange in the bent state to form a semicircular arc shape matching the bending curvature of the display panel. That is, the spacing (ΔL) of the support protrusions 230 needs to be adjusted according to the curvature radius when the display panel is bent, so as to ensure that the support protrusions can be evenly distributed on the bending curve of the display panel. Specifically, when the display panel is in the bent state, the arc length corresponding to the upper edge (regarded as an inner ring in the flattened state) and the arc length corresponding to the lower edge (regarded as an outer ring in the flattened state) of the closely arranged support protrusions 230 are different, and the arc length (L2) corresponding to the lower edge is always greater than the arc length (L1) corresponding to the upper edge, and this difference determines the spacing (ΔL) of the support protrusions, i.e., ΔL=(L2−L1)/n. The above formula ensures that in the bent state of the display panel, the support protrusions can form a continuous and uniform supporting surface according to the preset curvature radius, and avoids the formation of additional creases or damage of the display panel during bending.

At this time, the spacing between the adjacent support protrusions 230 may satisfy the following formula: ΔL=L2−L1=π×H/n. The above design can provide all-around support to the bendable region, which will not cause the bendable region to deform or wobble from side to side regardless of unbalanced support, which improves the stability of the bendable region, reduces creases, and prolongs the service life of the foldable screen.

Therefore, the embodiments of the present application can optimize the design according to the size of the bendable region of the display panel 10 and the required curvature, so as to ensure the structural stability and operation smoothness of the display panel 10 during bending. The support protrusions 230 with the optimized design ensure structural stability and operation smoothness of the display panel 10 during bending, avoid local damage of the display panel 10 during the bending process, and improve the stability and durability of the display module. The application scenarios include situations where a device needs to be bent frequently, such as the daily use of foldable screen mobile phones. This design can ensure the stability and smoothness of the screen when frequently bent and improve the user experience.

In some alternative embodiments, a side of at least one first support protrusion 231 of the plurality of support protrusions 230 close to the adjacent second support protrusion 232 is provided with a contact portion, and when the display module is in a bent state, the first support protrusion 231 is in contact with the second support protrusion 232 through the contact portion.

In the above-described alternative embodiments, the first support protrusion 231 is in contact with the second support protrusion 232 through the contact portion, the friction between the support protrusions 230 can be reduced when the display module is bent, and the stability of the support layer can be maintained.

In the above-described alternative embodiments, as shown in FIG. 11, the contact portion may be an accommodation protrusion 2310, and a side of the second support protrusion 232 close to the first support protrusion 231 may have an accommodation groove 2320 matching the accommodation protrusion 2310. At least part of the accommodation protrusion 2310 is located in the accommodation groove 2320 when the display module is in the bent state. This matching design of the accommodation protrusion 2310 and the accommodation groove 2320 reduces the friction between the support protrusions 230 when the display module is bent, ensures the smoothness of the screen bending, and improves the durability of the screen and the user experience.

Exemplarily, as shown in FIG. 11, the accommodation protrusion 2310 is spherical in shape, the accommodation groove 2320 has a concave surface, and the radius R3 of the accommodation protrusion 2310 is less than the radius R4 of the concave surface in the accommodation groove 2320. The matching between the accommodation protrusion 2310 in a convex spherical shape and the accommodation groove 2320 with a semicircular concave forms a connection mode similar to the ball and socket, which can enhance the stability between adjacent rectangular support protrusions 230 and prevent the support structure from sliding relatively during the bending process of the display module, thereby improving the structural stability of the entire support layer. Furthermore, when the spherical accommodation protrusion 2310 is in contact with the accommodation groove 2320 with the semicircular concave surface, it can provide a large contact area, which helps to disperse stress and reduce stress concentration points, thereby reducing creases when the screen is bent, and improving the durability and service life of the screen. In addition, the spherical structure has strong adaptability and can maintain good contact during bending at different angles. Even when the bending angle of the display module changes, the spherical structure can seamlessly adapt to ensure the continuity of the support protrusion 230 and stable support of the bendable region.

Further, it is also possible to reasonably design the size and position of the accommodation protrusion 2310 and the accommodation groove 2320 through precise calculations to ensure that the support protrusion 230 can form a continuous semicircular arc when the display screen is bent to a specific angle, thereby providing stable curvature support, thereby ensuring that the support layer can form a continuous semicircular arc when bent to a specific angle, providing stable curvature support, avoiding local damage of the display module during bending, and improving the stability and durability of the display module.

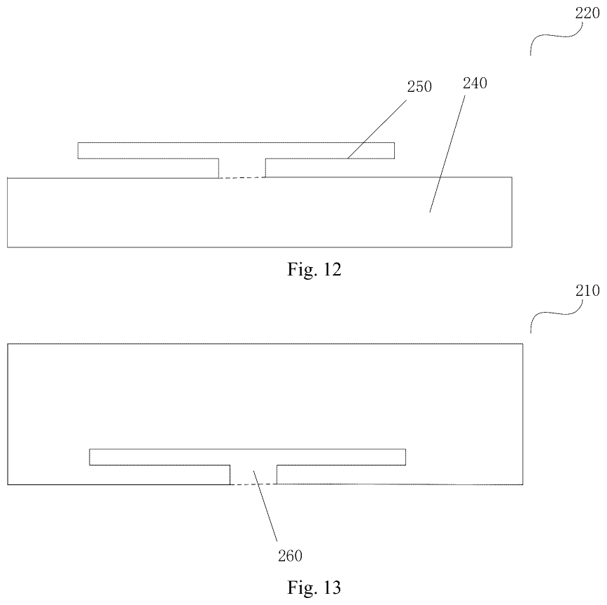

In some alternative embodiments, as shown in FIG. 12, the second support portion 220 further includes a base body 240 and a connection portion located on the base body 240, the connection portion being located on a side of the base body 240 close to the non-bendable region 120, and the second support portion 220 is connected to the first support portion 210 by the connection portion.

In the above-described alternative embodiments, the connection portion of the second support portion 220 can enhance the connection stability with the first support portion 210, and prevent gaps or separation caused by relative movement during the bending process of the display module.

In the alternative embodiments described above, as shown in FIGS. 12 and 13, the first support portion 210 may have an accommodation cavity 260 close to the second support portion 220, and the connection portion may be an embedded structure 250 embedded into and connected to the accommodation cavity 260.

Specifically, the connection portion may be designed in an “I” shape. In this case, by designing a matched accommodation cavity 260 in the first support portion 210, the second support portion 220 can form a mechanical snap-in connection with the first support portion 210, and this embedding-fitting can significantly enhance the connection stability between the first support portion 210 and the second support portion 220. Moreover, the embedded “I” shape design increases the area of the contact surface between the second support portion 220 and the first support portion 210, helps to improve the mechanical strength and rigidity of the entire support layer, and ensures the structural stability of the display module during folding and unfolding. In addition, the embedding-fitting design helps to realize the accurate positioning of the second support portion 220 between the non-bendable region 120 and the bendable region 110, to ensure the correct layout of the support protrusion 230 on the display panel 10, and to avoid affecting the folding performance of the display module due to positional deviation.

In some alternative embodiments, the support protrusion 230, the connection portion, and the base body 240 are integrally molded. The integrated design reduces the number of the seams in the support layer and avoids weakening of the joints, thereby improving the overall structural strength and stability of the second support portion 220. During the bending process, this seamless structure is better able to withstand stress and reduce wear and damage. Moreover, the integrally molded technology can control the size and shape of the second support portion 220 more accurately, ensure tight fit between the support protrusion 230, the connection portion, and the base body 240, reduce assembly problems due to manufacturing tolerances, and ensure smoothness and stability when the display module is folded.

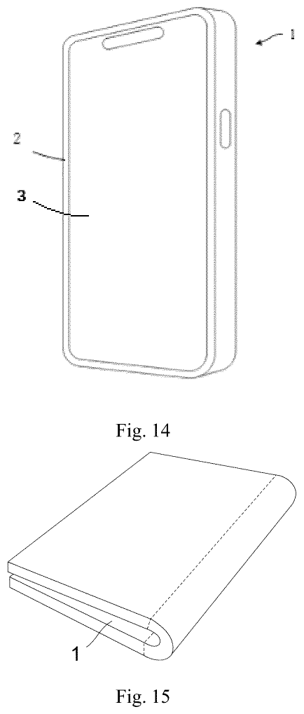

According to still another embodiment of the present application, as shown in FIG. 14, there is provided a display device 1 which includes the display module in any of the above embodiments. The display module includes a display panel and a support structure that are stacked, and the display panel has a display area 3 and a non-display area 2. The display device 1 may have the display module as shown in the above FIGS. 1, 3, 5 and 7, the display module including a display panel 10 and a support structure 20 that are stacked, and the display panel 10 including non-bendable regions 120 and a bendable region 110 connected between the two non-bendable regions 120. The bendable region 110 is bent toward a side facing away from the support structure 20 when the display module is in a bent state. The support structure 20 includes a first support portion 210 arranged corresponding to the non-bendable region 120, the first support portion 210 having a first hardness; the support structure 20 also includes a second support portion 220 at least corresponding to the bendable region 110, the second support portion 220 having a second hardness less than the first hardness.

FIG. 15 is a schematic structural diagram of the display device 1 as shown in FIG. 14 in a bent state, in which the bendable region 110 is bent toward the side facing away from the support structure 20 as shown in FIGS. 2, 4, 6, and 8. The second support portion 220 includes at least second support regions 222 and a first support region 221. The first support portion 210 is located between the second support region 222 and the non-bendable region 120. In this case, due to the second hardness of the second support region 222 being lower than the first hardness of the first support portion 210, the hardness of the support structure 20 gradually increases in the direction towards the non-bendable region 120, and the first support portion 210 with higher hardness can enhance the structural rigidity of the non-bendable region 120. At the same time, since the portion of the support structure 20 corresponding to the bendable region 110 is the second support portion 220 having the second hardness, the support structure 20 always maintains a low hardness in the direction towards the bendable region 110, so that both the non-bendable region 120 and the bendable region 110 of the display panel 10 can be effectively supported.

For example, taking for example that the display panel in the display device 1 is a foldable OLED display panel, the OLED display panel is mainly used in products such as foldable screen mobile phones, wearable devices, and portable e-readers. For example, in a foldable screen mobile phone, the bendable region 110 of the OLED display panel can realize the bending of the screen, which not only greatly reduces the size of the device and is convenient for carrying and storage, but also provides users with a larger screen display region, improving the multimedia and multitasking experience. In the design of the foldable screen mobile phone, the non-bendable region 120 of the display panel 10 is primarily used for fixing and supporting, while the bendable region 110 allows the screen to be folded when not in use to protect the display panel 10 from damage by external force.

Specifically, the display device may be an electronic device such as a mobile phone, a computer, and a television, and the display panel may be applied thereto.

In some optional embodiments, the OLED display panel includes a driving substrate, a light-emitting layer, and an encapsulation layer that are sequentially stacked, and the support structure in the display device is located on a side of the driving substrate facing away from the light-emitting layer. As an example, the driving substrate is a TFT substrate having thin film transistors therein. The light-emitting layer includes an anode layer, a cathode layer, and an organic light-emitting material layer formed between the anode layer and the cathode layer.

From the above description, it can be seen that the above-described embodiments of the present application realize at least some of the following technical effects:
1) Through the combination of the first support portion and the second support portion, the present application uses a material with higher hardness in the non-bendable region, and a material with lower hardness in the bendable region, corresponding to the bending characteristics of the non-bendable region of the display panel that requires hard support. The bendable region requires soft support, effectively improving the structural stability and durability of the screen, and avoiding bending deformation of the support layer after the display module is bent multiple times.
2) The support structure design that can also be optimized in the present application ensures the smoothness and uniform curvature of the display module when bent, reduces the friction and damage of the screen during frequent bending process, and significantly improves the user experience and service life of the foldable screen device. In practical applications, the design of the support structure in this application can adapt to a variety of folding modes to meet the needs of different users.

It should also be noted that the terms “comprise” “include” or any other variation thereof are intended to encompass a non-exclusive inclusion such that a process, method, commodity, or apparatus comprising a series of elements includes not only those elements, but also other elements not explicitly listed, or elements inherent to such a process, method, commodity, or apparatus. Without further limitation, an element defined by the statement “comprising a” does not preclude the presence of additional identical elements in the process, method, article, or apparatus comprising the element.

The above are merely examples of the present application, and are not intended to limit the present application. Various modifications and variations of the present application will be apparent to those skilled in the art. Any modification, equivalent substitution, improvement, etc. made within the spirit and principles of the present application should be included within the scope of the claims of the present application.

What is claimed is:

1. A display module comprising a display panel and a support structure that are stacked, the display panel comprising:
non-bendable regions and a bendable region connected between two said non-bendable regions, the bendable region being bent toward a side facing away from the support structure when the display module is in a bent state,
wherein the support structure comprises:
first support portions disposed corresponding to the non-bendable regions and having a first hardness; and
a second support portion disposed corresponding to at least the bendable region, the second support portion having a second hardness less than the first hardness.

2. The display module according to claim 1, wherein
the second support portion comprises a first support region and second support regions, the first support region being connected between two said second support regions, and
the first support portions are each located between the second support region and the non-bendable region.

3. The display module according to claim 2, wherein a thickness of the first support region is greater than a thickness of the first support portion in a first direction, the first direction being a direction perpendicular to a first surface of the display panel, and the first surface being a surface of the display panel opposite the support structure.

4. The display module according to claim 3, wherein the thickness of the first support region is a sum of a thickness of the second support region and the thicknesses of the first support portion.

5. The display module according to claim 1, wherein a material of the first support portion comprises a rigid material, and a material of the second support portion comprises a flexible material.

6. The display module according to claim 2, wherein the first support region has a plurality of support protrusions close to the bendable region.

7. The display module according to claim 6, wherein the second support portion comprises a base body and the plurality of support protrusions distributed on a side of the base body close to the display panel and having a same height.

8. The display module according to claim 7, wherein orthographic projections of the plurality of support protrusions on the display panel have a same area and a same shape.

9. The display module according to claim 8, wherein the shape of the orthographic projections of the support protrusions on the display panel is selected from any one or a combination of a rectangle, a trapezoid, a triangle, a diamond, and a parallelogram.

10. The display module according to claim 8, wherein
each of the support protrusions having the same shape has a second surface and a third surface that are opposite each other, the second surface being located on a side of the third surface close to the display panel, an orthographic projection of the third surface on the first surface of the display panel being located within an orthographic projection of the second surface on the first surface, and the first surface being the surface of the display panel opposite the support structure; or
each of the support protrusions having the same shape has a first sub-protrusion and a second sub-protrusion, the first sub-protrusion being located on a side of the second sub-protrusion close to the display panel and having a first orthographic projection on the first surface of the display panel, the second sub-protrusion having a second orthographic projection on the first surface of the display panel, a size of the first orthographic projection being less than a size of the second orthographic projection, the first surface being the surface of the display panel opposite the support structure.

11. The display module according to claim 7, wherein the plurality of support protrusions are arranged in at least one row on a side of the display panel, and an arrangement direction of the support protrusions in each row is a direction in which the bendable region points to the non-bendable region.

12. The display module according to claim 11, wherein any adjacent two of the support protrusions have a same spacing.

13. The display module according to claim 12, wherein the spacing between the adjacent two of the support protrusions satisfies a preset formula:
$$Δ L = π \times H / n ,$$
where ΔL is the spacing between the adjacent two of the support protrusions, H is a height of the support protrusions, and n is a number of the support protrusions located in a same row.

14. The display module according to claim 7, wherein a side of at least one first support protrusion of the plurality of support protrusions close to an adjacent second support protrusion has a contact portion, and the first support protrusion is in contact with the second support protrusion through the contact portion when the display module is in the bent state.

15. The display module according to claim 14, wherein the contact portion is an accommodation protrusion, a side of the second support protrusion close to the first support protrusion has an accommodation groove matching the accommodation protrusion, and at least part of the accommodation protrusion is positioned in the accommodation groove when the display module is in the bent state.

16. The display module according to claim 15, wherein the accommodation protrusion is in a spherical shape, the accommodation groove has a concave surface, and a radius of the accommodation protrusion is less than a radius of the concave surface.

17. The display module according to claim 6, wherein the second support portion further comprises a base body and a connection portion located on the base body, the connection portion being located on a side of the base body close to the non-bendable region, and the second support portion being connected to the first support portion through the connection portion.

18. The display module according to claim 17, wherein the first support portion has an accommodation cavity close to the second support portion, and the connection portion is an embedded structure embedded into and connected to the accommodation cavity.

19. The display module according to claim 17, wherein the support protrusions, the connection portion, and the base body are integrally molded.

20. A display device comprising the display module which comprises a display panel and a support structure that are stacked, the display panel comprising:
non-bendable regions and a bendable region connected between two said non-bendable regions, the bendable region being bent toward a side facing away from the support structure when the display module is in a bent state,
wherein the support structure comprises:
first support portions disposed corresponding to the non-bendable regions and having a first hardness; and
a second support portion disposed corresponding to at least the bendable region, the second support portion having a second hardness less than the first hardness.
